(19) United States
(12) Patent Application Publication
(10) Pub. No.: US 2022/0139942 A1
(43) Pub. Date: May 5, 2022

(54) SEMICONDUCTOR DEVICE

(71) Applicant: Tokyo Electron Limited, Tokyo (JP)

(72) Inventors: Genji NAKAMURA, Yamanashi (JP); Keisuke SUZUKI, Yamanashi (JP); Kimiya AOKI, Yamanashi (JP)

(73) Assignee: Tokyo Electron Limited, Tokyo (JP)

(21) Appl. No.: 17/578,468

(22) Filed: Jan. 19, 2022

Related U.S. Application Data
(63) Continuation of application No. PCT/JP2020/027188, filed on Jul. 13, 2020.

(30) Foreign Application Priority Data
Jul. 26, 2019 (JP) 2019-137927

(51) Int. Cl. H01L 27/11551; H01L 27/11578; H01L 21/28

(52) U.S. Cl. CPC H01L 27/11551; H01L 29/4011; H01L 27/11578

(57) ABSTRACT

A semiconductor device includes an electric-charge storing film, an electrode, a first block film, and a second block film. The first block film is arranged between the electric-charge storing film and the electrode.

The second block film is arranged between the first block film and the electric-charge storing film. The first block film is an oxide film containing tantalum, and an electric permittivity of the first block film is larger than an electric permittivity of the second block film.

### CROSS-REFERENCE TO RELATED APPLICATIONS

This application is a continuation application of International Application PCT/JP2020/027188, filed on Jul. 13, 2020, and claims priority to Japanese Application No. 2019-137927, filed Jul. 26, 2019, the entire contents of each are incorporated herein by reference.

### FIELD

Exemplary embodiments disclosed herein relate to a semiconductor device.

### BACKGROUND

In a semiconductor device such as a flash memory, there has been known a structure in which memory cells are three-dimensionally arranged in order to increase degree of integration.

Patent Literature 1: U.S. Unexamined Patent Application Publication No. 2015/0155297

### SUMMARY

According to an aspect of an embodiment, a semiconductor device includes an electric-charge storing film, an electrode, a first block film, and a second block film. The first block film is arranged between the electric-charge storing film and the electrode. The second block film is arranged between the first block film and the electric-charge storing film. The first block film is an oxide film containing tantalum. An electric permittivity of the first block film is larger than an electric permittivity of the second block film.

### BRIEF DESCRIPTION OF DRAWINGS

FIG. 1 is a schematic cross-sectional view illustrating one example of a semiconductor device of a first embodiment according to the present disclosure.

FIG. 2 is a partial exploded view illustrating one example of a structure of a part in a region A illustrated in FIG. 1.

FIG. 3 is a diagram illustrating one example of features of various films.

FIG. 4 is a diagram illustrating one example of a manufacturing process of a semiconductor device.

FIG. 5 is a diagram illustrating one example of a manufacturing process of the semiconductor device.

FIG. 6 is a diagram illustrating one example of a manufacturing process of the semiconductor device.

FIG. 7 is a diagram illustrating one example of a manufacturing process of the semiconductor device.

FIG. 8 is a diagram illustrating one example of a manufacturing process of the semiconductor device.

FIG. 9 is a diagram illustrating one example of a manufacturing process of the semiconductor device.

FIG. 10 is a diagram illustrating one example of a manufacturing process of the semiconductor device.

FIG. 11 is a partial exploded view illustrating a structure of a part in a region A according to a comparison example 1.

FIG. 12 is a partial exploded view illustrating a structure of a part in a region A according to a comparison example 2.

FIG. 13 is a diagram illustrating one example of relation between energy levels in the structure illustrated in FIG. 12.

FIG. 14 is a diagram illustrating one example of relation between energy levels in the structure illustrated in FIG. 2.

FIG. 15 is a partial exploded view illustrating one example of a structure of a part in a region A according to a second embodiment.

FIG. 16 is a diagram illustrating one example of relation between energy levels in the structure illustrated in FIG. 15.

FIG. 17 is a partial exploded view illustrating one example of a structure of a part in a region A according to a third embodiment.

FIG. 18 is a diagram illustrating one example of relation between energy levels in the structure illustrated in FIG. 17.

FIG. 19 is a partial exploded view illustrating another example of a structure of a part in the region A according to the first embodiment.

### DESCRIPTION OF EMBODIMENT

Exemplary embodiments of a semiconductor device disclosed in the present application will be described below in detail with reference to the accompanying drawings. In addition, the illustrative embodiments disclosed below are not intended to limit the disclosed semiconductor device.

For example, in a case where manufacturing a semiconductor device in which memory cells are three-dimensionally arranged, a structure is manufactured in which insulation films and sacrificial films are alternately laminated, and a through hole is formed in a position where a bit line is arranged, which penetrates through the insulation films and the sacrificial films in a lamination direction of the insulation films and the sacrificial films. A block film, an electric-charge storing film, and an insulation film are laminated on a side wall of the through hole, and an electrode material to be a channel connected to the bit line is embedded in the through hole.

Next, the sacrificial films are removed by wet etching, and thus a hole is formed between the insulation layers. Aluminum oxide and titanium nitride are laminated in the hole. Next, tungsten to be an electrode connected to a word line is embedded in the hole on which titanium nitride is laminated.

Incidentally, when high integration of a semiconductor device is accelerated, Critical Dimension (CD) of a hole between insulation layers becomes small. Aluminum oxide and titanium nitride need to be laminated on the hole, and thus CD of an electrode reduces when CD of the hole is reduced. When CD of the electrode is reduced, a resistance value of the electrode increases, thereby leading to increase in power consumption and heat generation.

Therefore, a case may be considered in which a material of the electrode is made of a metal other than tungsten while omitting a layer of titanium nitride, and aluminum oxide laminated in the hole between the insulation layers is arranged on a side of the through hole formed in a position where a bit line is arranged. Thus, it is possible to increase CD of the electrode formed in the hole between insulation layers.

However, an etching rate of aluminum oxide is high with respect to phosphoric acid that is used in wet etching. Thus, a film made of a material having a high tolerant against phosphoric acid, such as silicon oxide, is to be interposed between a sacrificial film and aluminum oxide.

However, in a semiconductor device having such a structure, there presents a problem that leakage of an electron is large between an electrode formed after removal of a sacrificial film and an electric-charge storing film. Thus, the present disclosure provides a technology for preventing leakage of an electron between an electrode and an electric-charge storing film.

### First Embodiment

[Structure of Semiconductor Device 10]

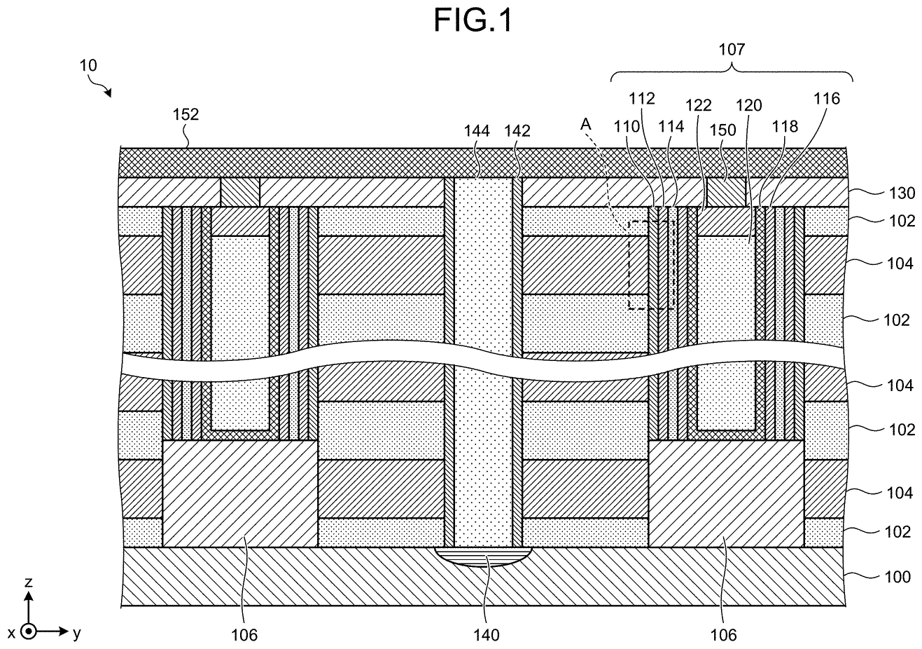

FIG. 1 is a schematic cross-sectional view illustrating one example of a semiconductor device 10 of a first embodiment according to the present disclosure. For example, as illustrated in FIG. 1, the semiconductor device 10 includes a substrate 100 such as bulk silicon. On the substrate 100, a plurality of interlayer insulating films 102 and a plurality of electrodes 104 are alternately laminated in a z-direction illustrated in FIG. 1. In the present embodiment, the interlayer insulating film 102 is made of silicon oxide (SiO₂), for example, and the electrode 104 is made of a metal other than tungsten, for example. The electrode 104 functions as gate a electrode of a word line.

A bit line 152 is provided, via a cap layer 130, on the interlayer insulating films 102 and the electrodes 104 that are alternately laminated. The substrate 100 is provided with a common-source region 140, and a spacer 142 made of an insulating material and an element separating insulation film 144 are provided on the common-source region 140.

A semiconductor pattern 106 made of, e.g. monocrystalline silicon or the like is formed on the substrate 100, and a columnar structure 107 extending in the z-direction illustrated in FIG. 1 is provided on the semiconductor pattern 106. The columnar structure 107 includes an Hi-k film 110, a block film 112, an electric-charge storing film 114, an insulation film 116, a channel 118, an insulator 120, a pad 122, and a contact 150.

The channel 118 is formed of, e.g. polycrystalline silicon or the like so as to cylindrically extend in the z-direction illustrated in FIG. 1, for example. A lower surface of the channel 118 is electrically connected to the substrate 100 via the semiconductor pattern 106. An upper part of the channel 118 is electrically connected to the pad 122.

The insulator 120 is formed of, e.g. silicon oxide, and is embedded in a space formed by inner walls of the channel 118. The pad 122 is arranged on the insulator 120. The electric-charge storing film 114 made of, e.g. silicon nitride is arranged at a periphery of the channel 118 via the insulation film 116 made of, e.g. silicon oxide.

The Hi-k film 110 is arranged at a periphery of the electric-charge storing film 114 via the block film 112. In other words, the Hi-k film 110 is arranged between the electrode 104 and the electric-charge storing film 114, and the block film 112 is arranged between the Hi-k film 110 and the electric-charge storing film 114. In the present embodiment, the Hi-k film 110 is an oxide film containing tantalum and silicon. In the present embodiment, an electric permittivity of the Hi-k film 110 is larger than an electric permittivity of the block film 112. The Hi-k film 110 is one example of a first block film, and the block film 112 is one example of a second block film.

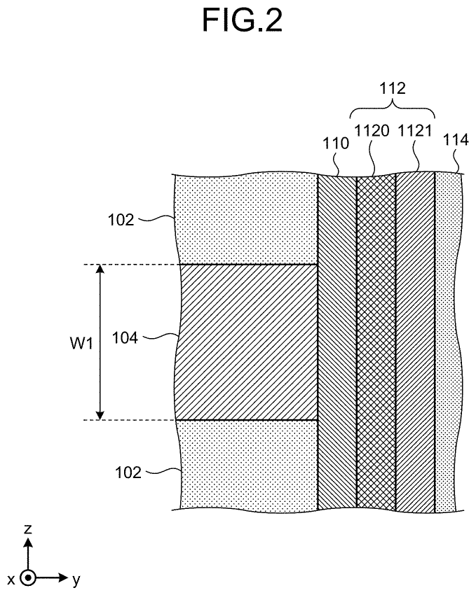

FIG. 2 is a partial exploded view illustrating one example of a structure of a part in a region A illustrated in FIG. 1. For example, as illustrated in FIG. 2, the Hi-k film 110 and the block film 112 are arranged between the electrode 104 and the electric-charge storing film 114. The block film 112 is arranged closer to the electric-charge storing film 114 than the Hi-k film 110. CD of the electrodes 104 according to the present embodiment is defined as W1.

In the present embodiment, the block film 112 includes a block film 1120 and a block film 1121. The block film 1120 is one example of a third block film, and the block film 1121 is one example of a fourth block film. The block film 1120 is arranged between the Hi-k film 110 and the block film 1121. In the present embodiment, the block film 1120 is formed of a material that is made of aluminum oxide, for example. The block film 1121 is formed of a material that is made of silicon oxide, for example.

In the present embodiment, the block film 1120 is annealed at a high temperature (for example, 1000° C.) after film formation so as to be a crystalline film. In the present embodiment, the block film 1121 is an amorphous film. Leakage of an electron between the electrode 104 and the electric-charge storing film 114 is prevented by the Hi-k film 110, the block film 1120, and the block film 1121.

The Hi-k film 110 contains tantalum, and tantalum has an electric conductivity. Thus, current leaks in some cases via the Hi-k film 110 from the other electrode 104 that is adjacent via the interlayer insulating film 102. Therefore, in the present embodiment, the Hi-k film 110 contains silicon having a resistance value that is higher than that of tantalum.

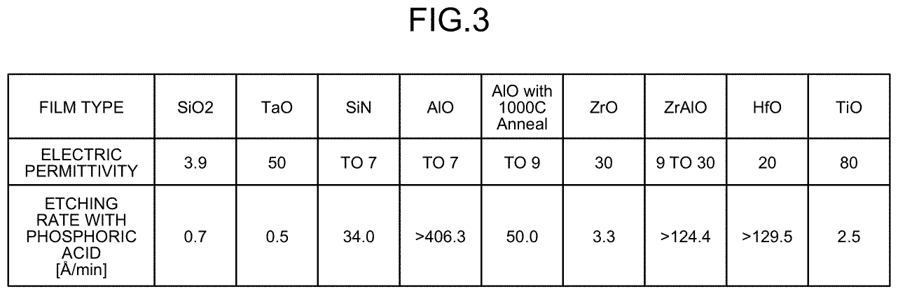

For example, with reference to FIG. 3, an electric permittivity of silicon oxide is 3.9, an electric permittivity of tantalum oxide is 50, and an electric permittivity of an annealed aluminum oxide is approximately 9. In the Hi-k film 110, the larger a content of silicon is, the closer to an electric permittivity of silicon oxide an electric permittivity of the Hi-k film 110 is. In the Hi-k film 110, when a content of silicon is equal to or more than eight times as large as a content of tantalum, an electric permittivity of the Hi-k film 110 is equal to or less than nine. In the Hi-k film 110 according to the present embodiment, a content of silicon is less than eight times as large as a content of tantalum. Thus, it is possible to increase an electric permittivity of the Hi-k film 110 so as to be larger than an electric permittivity the block film 112.

[Manufacturing Procedure of Semiconductor Device 10]

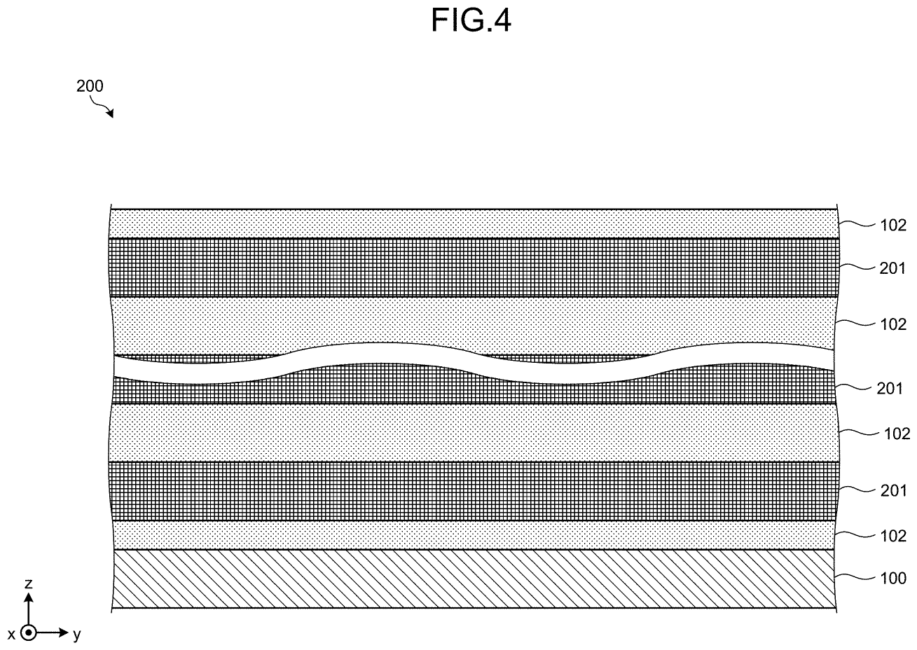

Next, a manufacturing procedure of the semiconductor device 10 will be explained with reference to FIGS. 4 to 10. FIGS. 4 to 10 are diagrams illustrating one example of a manufacturing process of the semiconductor device.

For example, as illustrated in FIG. 4, a structure 200 is prepared in which the interlayer insulating films 102 and sacrificial films 201 are alternately laminated on the semiconductor device 10 in the z-direction illustrated in FIG. 4. In the present embodiment, the sacrificial film 201 is made of silicon nitride, for example.

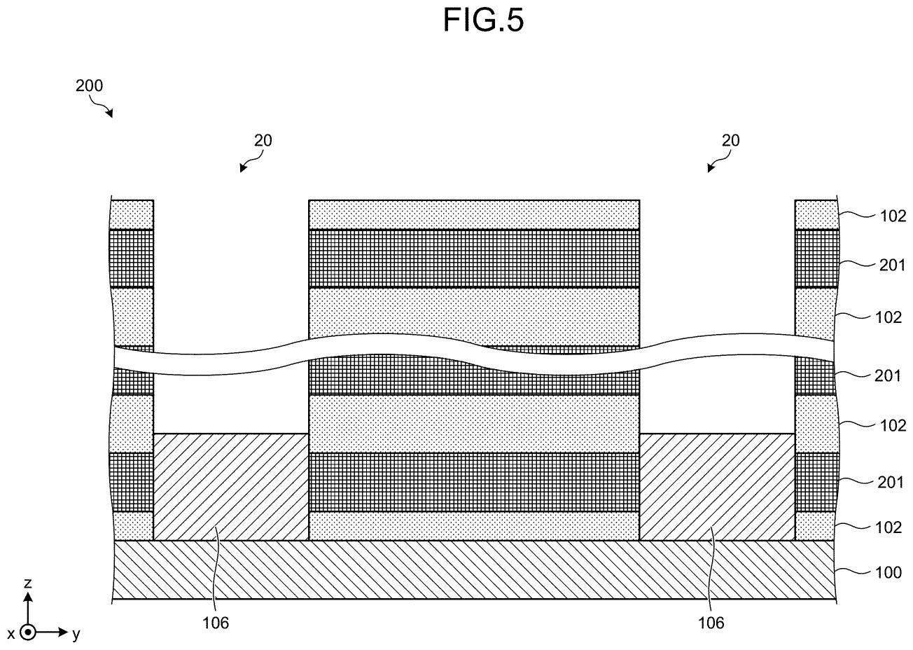

Next, for example, as illustrated in FIG. 5, holes 20 are formed, by dry etching or the like, in positions of the structure 200 in which the columnar structures 107 are formed. The semiconductor patterns 106 are laminated on bottom portions of the holes 20 by a Chemical Vapor Deposition (CVD) or the like.

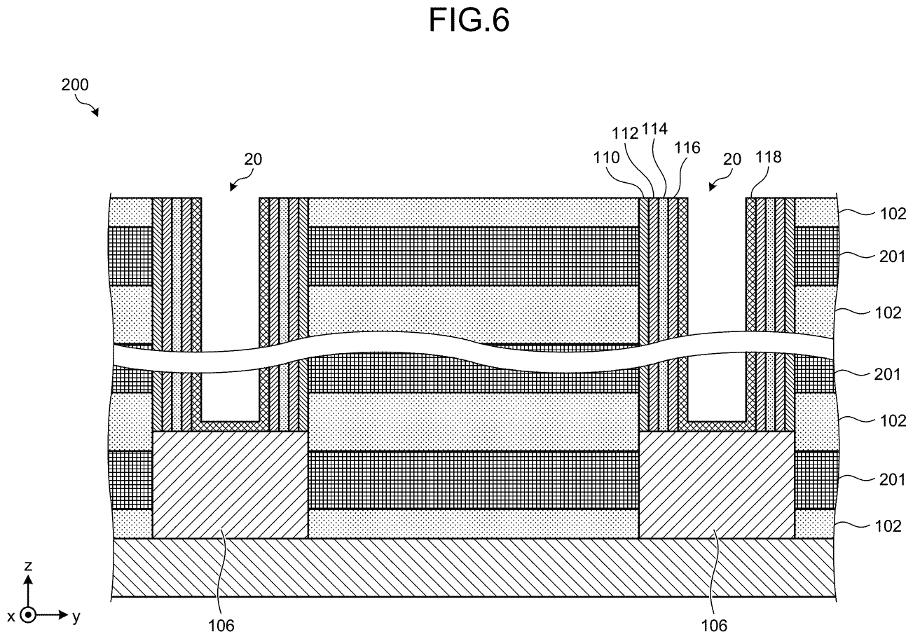

Next, for example, as illustrated in FIG. 6, the Hi-k film 110, the block film 112, the electric-charge storing film 114, and the insulation film 116 are laminated on a side wall of each of the holes 20 by an Atomic Layer Deposition (ALD), for example, and then the channel 118 is laminated thereon by a heat CVD. In the present embodiment, the block film 112 includes the block film 1120 and the block film 1121. The block film 1120 is laminated, after the Hi-k film 110 is laminated thereon, on the Hi-k film 110 by ALD, for example, and then is annealed in an atmosphere of 1000° C. to be crystallized, for example. The block film 1121 is laminated on the crystallized block film 1120 by ALD, for example.

In the ALD, an ALD cycle including an adsorption process, a first purge process, a reaction process, and a second purge process is repeated a plurality of times so that a target film is laminated. In the adsorption process, precursor gas is supplied to a surface of a region to be a film-formation target so that molecules of the precursor gas are adsorbed on the region of the film-formation target.

In the first purge process, inert gas is supplied to the surface of the region to be the film-formation target so that molecules of excessively-adsorbed precursor gas are removed. In the reaction process, reactant gas is supplied to the surface of the region to be the film-formation target so that molecules of the precursor gas and molecules of the reactant gas react with each other, which are adsorbed on the surface of the region to be the film-formation target, and a target film is formed. In the second purge process, inert gas is supplied to the region to be the film-formation target so that molecules of the excessively-supplied reactant gas are removed.

When the ALD cycle is executed once, a target film having a thickness of one atomic layer is laminated on a region to be a film-formation target. Thus, when the repetition number of the ALD cycle is controlled, a thickness of a film to be formed is able to be controlled with high accuracy.

The Hi-k film 110 is an oxide film containing tantalum and silicon, and a content of silicon is less than eight times as large as a content of tantalum. In the present embodiment, a ratio between, for example, a film thickness of tantalum oxide formed by ALD and, for example, a film thickness of silicon oxide formed by ALD is controlled, thereby leading to controlling a ratio between tantalum and silicon contained in the Hi-k film 110. In the formation of the Hi-k film 110, the repetition number of ALD cycle in forming silicon oxide is controlled so as to be less than eight times as large as the repetition number of ALD cycle in forming tantalum oxide. For example, in the formation of the Hi-k film 110, an ALD cycle in forming silicon oxide and an ALD cycle in forming tantalum oxide may be alternately executed one-by-one. A film thickness of the Hi-k film 110 is 0.5 [nm] to 1 [nm], for example.

In the formation of tantalum oxide by ALD, e.g. gas of PentaEthoxy Tantalum (PET) is used as precursor gas, e.g. plasma of O2 gas is used as reactant gas, and e.g. N2 gas is used as inert gas. In the formation of silicon oxide by ALD, e.g. gas of HexaChloro Disilane (HCD) is used as precursor gas, e.g. plasma of O2 gas is used as reactant gas, and e.g. N2 gas is used as inert gas.

In the formation of the block film 1120 made of aluminum oxide by ALD, e.g. gas of TriMethylAluminium (TMA) is used as precursor gas, e.g. plasma of O2 gas is used as reactant gas, and e.g. N2 gas is used as inert gas. After the block film 1120 is formed, the structure 200 is annealed in an atmosphere of 1000° C., for example, so that the block film 1120 is crystallized. A film thickness of the block film 1120 is 2 [nm] to 4 [nm], for example.

In the formation of the block film 1121 made of silicon oxide by ALD, e.g. gas of HCD is used as precursor gas, e.g. plasma of O2 gas is used as reactant gas, and e.g. N2 gas is used as inert gas. A film thickness of the block film 1121 is 5 [nm] to 7 [nm], for example. In the formation of the electric-charge storing film 114 by ALD, e.g. gas of DiChloroSilane (DCS) is used as precursor gas, e.g. plasma of gas of NH3 is used as reactant gas, and e.g. Ar gas is used as inert gas. A film thickness of the electric-charge storing film 114 is 3 [nm] to 5 [nm], for example.

In the formation of the insulation film 116 by ALD, e.g. gas of HCD is used as precursor gas, e.g. plasma of O2 gas is used as reactant gas, and e.g. N2 gas is used as inert gas. In the film formation of the channel 118 by heat CVD, gas obtained by mixing monosilane (SiH4) or disilane (Si2H6) and H2 gas to each other is used.

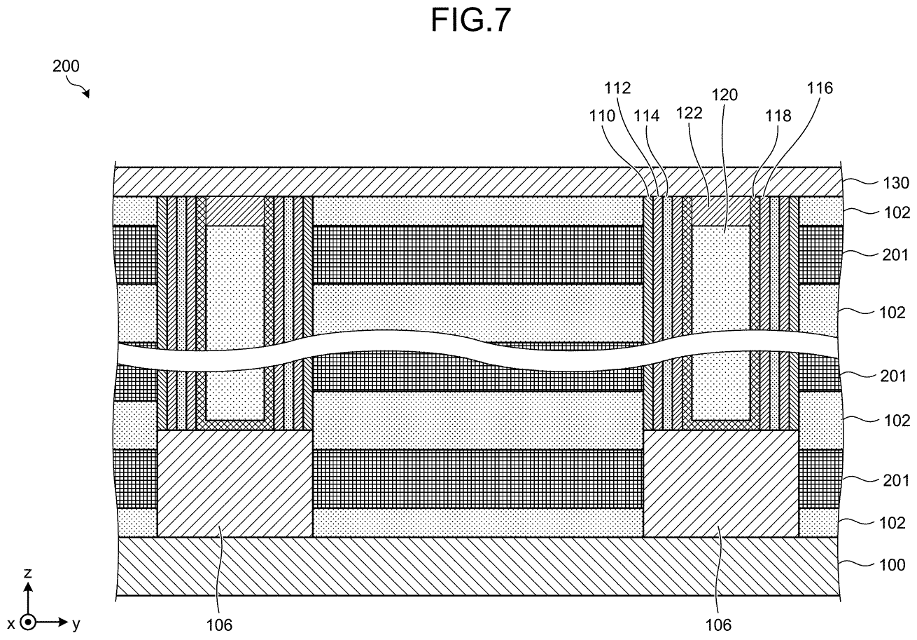

Next, for example, as illustrated in FIG. 7, the insulator 120 is embedded in the hole 20 on which the channel 118 is laminated, and the pad 122 is formed on the insulator 120. The cap layer 130 made of silicon oxide or the like is laminated on an upper surface of the structure 200.

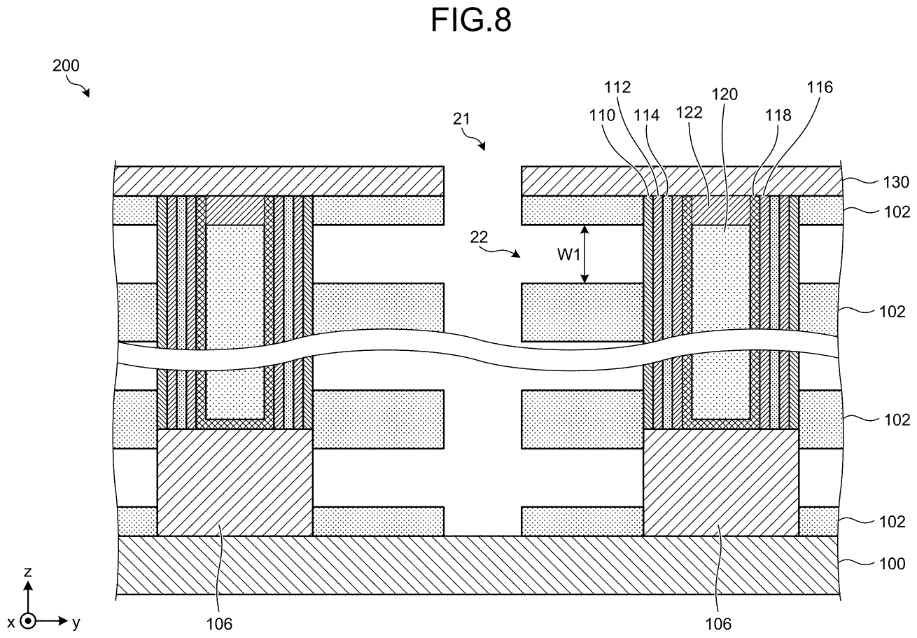

Next, for example, as illustrated in FIG. 8, a hole 21 is formed, by dry etching or the like, in a position of the structure 200 at which the spacer 142 and the element separating insulation film 144 are to be arranged. The sacrificial films 201 arranged between the interlayer insulating films 102 are removed by wet etching using phosphoric acid. Thus, between the interlayer insulating films 102 that are adjacent to each other in the z-direction illustrated in FIG. 8, a hole 22 whose CD is W1 is formed.

Herein, with reference to FIG. 3, a film type whose etching rate with phosphoric acid is approximately equal to or less than that of silicon oxide is tantalum oxide among the film types exemplified in FIG. 3. Among the film types exemplified in FIG. 3, etching rates with phosphoric acid of film types other than tantalum oxide are larger than that of silicon oxide. Thus, among the film types exemplified in FIG. 3, a material provided to a periphery of the hole 22 needs to be silicon oxide, tantalum oxide, or a compound thereof, which has resistance against phosphoric acid.

In the present embodiment, the Hi-k film 110 is made of an oxide containing tantalum and silicon, and thus an etching rate with phosphoric acid is between an etching rate of tantalum oxide and an etching rate of silicon oxide. Thus, when the sacrificial films 201 are removed by wet etching using phosphoric acid, the Hi-k film 110 is hardly etched, so that it is possible to form the hole 22 having a desired shape.

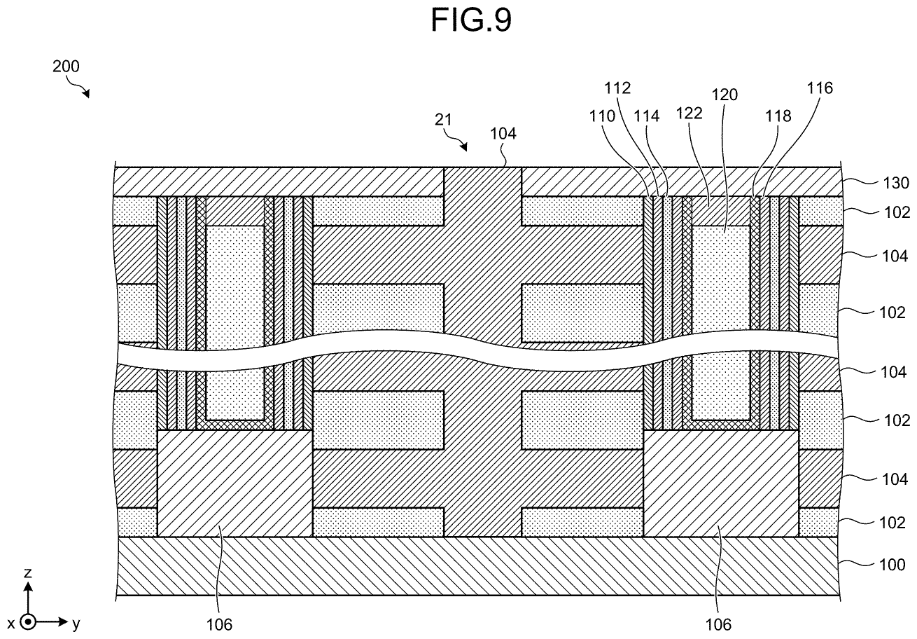

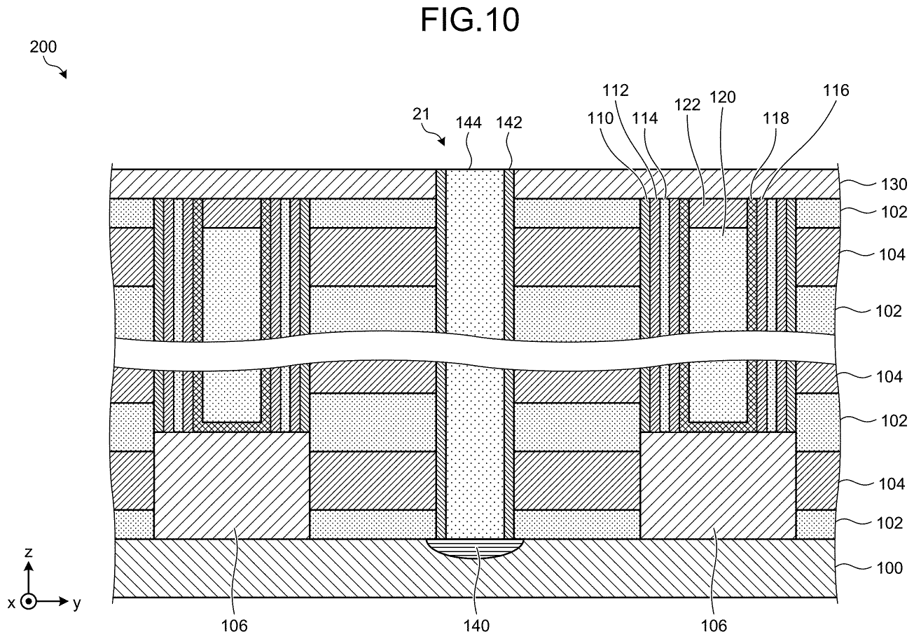

Next, for example, as illustrated in FIG. 9, a material of the electrodes 104 is embedded between the interlayer insulating films 102 via a hole 21. For example, as illustrated in FIG. 10, the hole 21 is formed again by dry etching or the like, an impurity such as phosphorus is injected into a bottom portion of the hole 21 so as to form the common-source region 140. The spacer 142 is laminated on a side wall of the hole 21, and the element separating insulation film 144 is embedded in the hole 21 on which the spacer 142 is laminated.

Next, the contact 150 is formed on the pad 122, and the bit line 152 is laminated on the cap layer 130. The bit line 152 and the contact 150 are electrically connected to each other. Thus, for example, the semiconductor device 10 illustrated in FIG. 1 is formed.

### COMPARISON EXAMPLE 1

Herein, a comparison example 1 will be explained. FIG. 11 is a partial exploded view illustrating a structure of a part in the region A according to the comparison example 1. In the comparison example 1, a block film 162 made of silicon oxide is arranged between the sacrificial film 201 and the electric-charge storing film 114.

In the comparison example 1, after the sacrificial films 201 between the interlayer insulating films 102 that are adjacent to each other in the z-direction illustrated in FIG. 11 are removed by wet etching, a block film 160 made of aluminum oxide is laminated on a side wall of the hole 22. A barrier film 161 made of titanium nitride is laminated on the block film 160, and a material of an electrode 104′ made of tungsten is embedded in the hole 22 on which the barrier film 161 is laminated.

In the comparison example 1, the block film 160 and the barrier film 161 are laminated in the hole 22, and thus CD of the electrodes 104′ is W2 that is smaller than W1. When high integration of the semiconductor device 10 is accelerated, W1 that is CD of the hole 22 increases, and W2 that is CD of the electrodes 104′ accordingly reduces. When CD of the electrodes 104′ reduces, a resistance value of the electrodes 104′ increases, and power consumption and/or heat generation of the semiconductor device 10 increases.

The barrier film 161 is a film needed for not only growing the electrode 104′ made of tungsten in the hole 22, but also preventing diffusion of atoms of tungsten. However, if the electrode 104′ made of tungsten is replaced with the electrode 104 made of a metal other than tungsten, the barrier film 161 becomes unnecessary to be able to expand CD of the electrode 104.

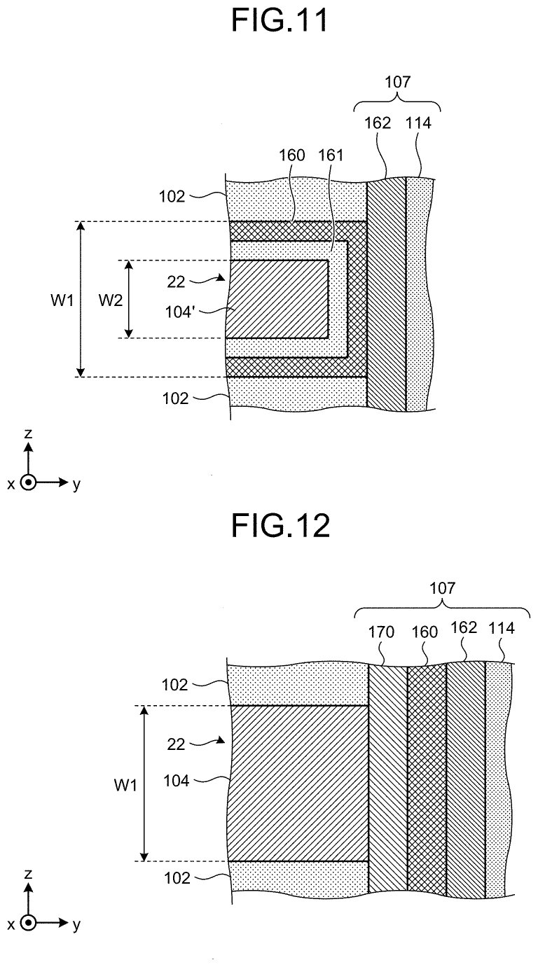

Furthermore, for example, as indicated in a comparison example 2 illustrated in FIG. 12, a case may be considered in which the block film 160 is included in the columnar structure 107 so as to expand CD of the electrode 104 up to W1. FIG. 12 is a partial exploded view illustrating a structure of a part in the region A according to the comparison example 2. Thus, compared with the electrode 104′ according to the comparison example 1, CD of the electrode 104 is able to be increased up to W1, so that it is possible to reduce power consumption and heat generation of the semiconductor device 10.

Herein, with reference to FIG. 3, an etching rate of aluminum oxide with phosphoric acid is large. Thus, in a case where the sacrificial film 201 and the block film 160 made of aluminum oxide are adjacent to each other, the block film 160 is etched when the sacrificial film 201 is removed by wet etching using phosphoric acid. Thus, in the comparison example 2, a block film 170 made of silicon oxide, whose etching rate with phosphoric acid is small, is to be interposed between the sacrificial film 201 and the block film 160.

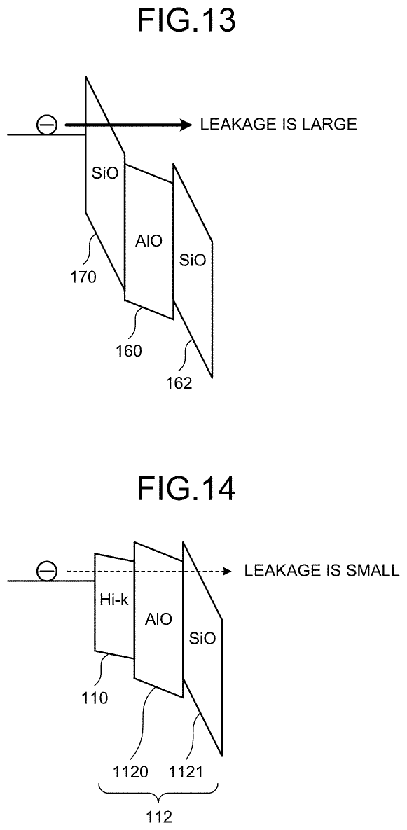

Herein, relation between energy levels of the block film 170, the block film 160, and the block film 162 is illustrated in FIG. 13, for example. FIG. 13 is a diagram illustrating one example of relation between energy levels in the structure illustrated in FIG. 12. The lower an electric permittivity is, or the farther a position is separated from the electrode 104, the more a height of energy barrier reduces steeply. For example, as illustrated in FIG. 3, an electric permittivity of silicon oxide is 3.9, and an electric permittivity of annealed aluminum oxide is approximately 9. Thus, a height of barrier of each of the block film 170 and the block film 162 that are made of silicon oxide more steeply reduces as a position is separated from the electrode 104 than a case of the block film 160 made of aluminum oxide. Thus, in the structure of the comparison example 2, a thin barrier of the block film 170 alone presents between the electrode 104 and the electric-charge storing film 114, and thus leakage of an electron between the electrode 104 and the electric-charge storing film 114 becomes large.

On the other hand, in the semiconductor device 10 according to the present embodiment, for example, as illustrated in FIG. 2, the Hi-k film 110, the block film 1120, and the block film 1121 are arranged between the electrode 104 and the electric-charge storing film 114. The Hi-k film 110 is an oxide film containing tantalum and silicon, and an electric permittivity of the Hi-k film 110 is larger than an electric permittivity of the block film 1120 made of aluminum oxide. An electric permittivity of the block film 1120 made of aluminum oxide is larger than an electric permittivity of the block film 1121 made of silicon oxide.

Thus, relation between energy levels of the Hi-k film 110, the block film 1120, and the block film 1121 is illustrated in FIG. 14, for example. FIG. 14 is a diagram illustrating one example of relation between energy levels in the structure illustrated in FIG. 2. An electric permittivity of the Hi-k film 110 is larger than an electric permittivity of the block film 1120 made of aluminum oxide, and thus reduction of the Hi-k film 110 in a height of barrier according to a distance from the electrode 104 is smaller than that of the block film 1120. An electric permittivity of the block film 1120 made of aluminum oxide is larger than an electric permittivity of the block film 1121 made of silicon oxide, and thus reduction of the block film 1120 in a height of barrier according to a distance from the electrode 104 is smaller than that of the block film 1121. Thus, for example, as illustrated in FIG. 14, barriers of the Hi-k film 110, the block film 1120, and the block film 1121 present between the electrode 104 and the electric-charge storing film 114 so as to prevent leakage of an electron between the electrode 104 and the electric-charge storing film 114.

As described above, the Hi-k film 110, the block film 1120, and the block film 1121 are arranged in the order of reducing electric permittivity from the electrode 104 to the electric-charge storing film 114, so that it is possible to prevent leakage of an electron between the electrode 104 and the electric-charge storing film 114.

The Hi-k film 110 according to the present embodiment is an oxide film containing tantalum and silicon, and an electric permittivity of the Hi-k film 110 is controlled to be larger than an electric permittivity of the block film 1120 made of aluminum oxide. Thus, compared with the comparison example 2, an electric permittivity of a film arranged between the electrode 104 and the electric-charge storing film 114 is able to be large. When an electric permittivity of a film arranged between the electrode 104 and the electric-charge storing film 114 is large, an operation voltage of writing and reading operation is able to be reduced. Thus, power consumption of the semiconductor device 10 is able to be more reduced.

As described above, the first embodiment is explained. As described above, the semiconductor device 10 according to the present embodiment includes the electric-charge storing film 114, the electrode 104, the Hi-k film 110, and the block film 112. The Hi-k film 110 is arranged between the electric-charge storing film 114 and the electrode 104. The block film 112 is arranged between the Hi-k film 110 and the electric-charge storing film 114. The Hi-k film 110 contains tantalum oxide, and an electric permittivity of the Hi-k film 110 is larger than an electric permittivity of the block film 112. Thus, it is possible to prevent leakage of an electron between the electrode 104 and the electric-charge storing film 114.

In the above-mentioned first embodiment, the block film 112 includes the block film 1120 made of aluminum oxide and the block film 1121 made of silicon oxide. The block film 1120 is arranged between the Hi-k film 110 and the block film 1121. Thus, the Hi-k film 110, the block film 1120, and the block film 1121 are arranged in the order of reducing electric permittivity from the electrode 104 to the electric-charge storing film 114, so that it is possible to prevent leakage of an electron between the electrode 104 and the electric-charge storing film 114.

In the above-mentioned first embodiment, the Hi-k film 110 contains silicon, and in the Hi-k film 110, a content of silicon is less than eight times as large as a content of tantalum. Thus, an electric permittivity of the Hi-k film 110 is able to be larger than an electric permittivity of the block film 112.

### Second Embodiment

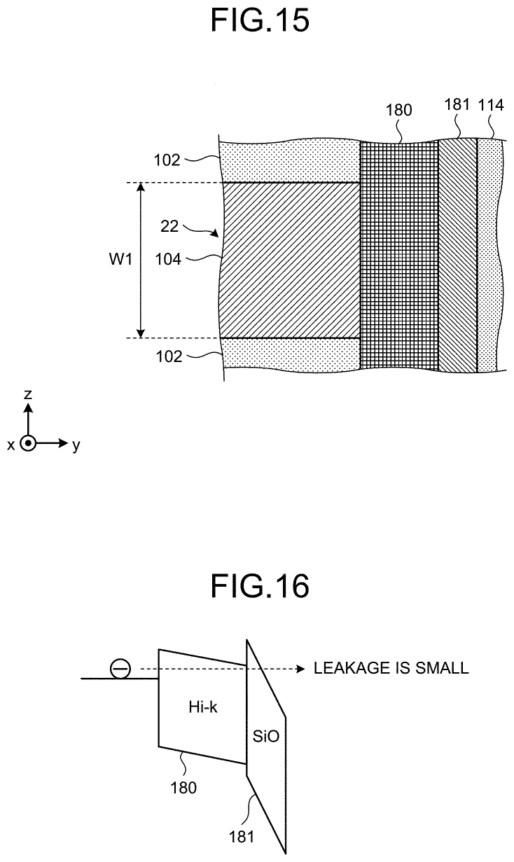

In the above-mentioned first embodiment, the Hi-k film 110 that is an oxide film containing tantalum and silicon, the block film 1120 made of aluminum oxide, and the block film 1121 made of silicon oxide are arranged between the electrode 104 and the electric-charge storing film 114. On the other hand, in the present embodiment, for example, as illustrated in FIG. 15, an Hi-k film 180 that is an oxide film containing tantalum and silicon and a block film 181 made of silicon oxide may be arranged between the electrode 104 and the electric-charge storing film 114.

FIG. 15 is a partial exploded view illustrating one example of a structure of a part in the region A according to a second embodiment. In the present embodiment, a film thickness of the Hi-k film 180 is, for example, 3 [nm] to 5 [nm], a film thickness of the block film 181 is, for example, 5 [nm] to 7 [nm], and a film thickness of the electric-charge storing film 114 is, for example, 3 [nm] to 5 [nm]. The Hi-k film 180 is formed such that a thickness thereof is approximately equal to a total thickness of the Hi-k film 110 and the block film 1120 according to the first embodiment. The Hi-k film 180 is one example of the first block film, and the block film 181 is one example of the second block film.

With reference to FIG. 3, an electric permittivity of tantalum oxide is 50, and an electric permittivity of silicon oxide is 3.9. Thus, even if a small amount of tantalum is contained in the Hi-k film 180 that is an oxide film containing tantalum and silicon, an electric permittivity of the Hi-k film 180 is larger than an electric permittivity of silicon oxide. Thus, in the semiconductor device 10 according to the present embodiment, the Hi-k film 180 and the block film 181 are arranged in the order of reducing electric permittivity from the electrode 104 to the electric-charge storing film 114.

FIG. 16 is a diagram illustrating one example of relation between energy levels in the structure illustrated in FIG. 15. An electric permittivity of the Hi-k film 180 is larger than an electric permittivity of the block film 181 made of silicon oxide, and thus reduction in a height of barrier of the Hi-k film 180 according to a distance from the electrode 104 is looser than that of the block film 181. Thus, in the present embodiment, it is also possible to prevent leakage of an electron between the electrode 104 and the electric-charge storing film 114.

### Third Embodiment

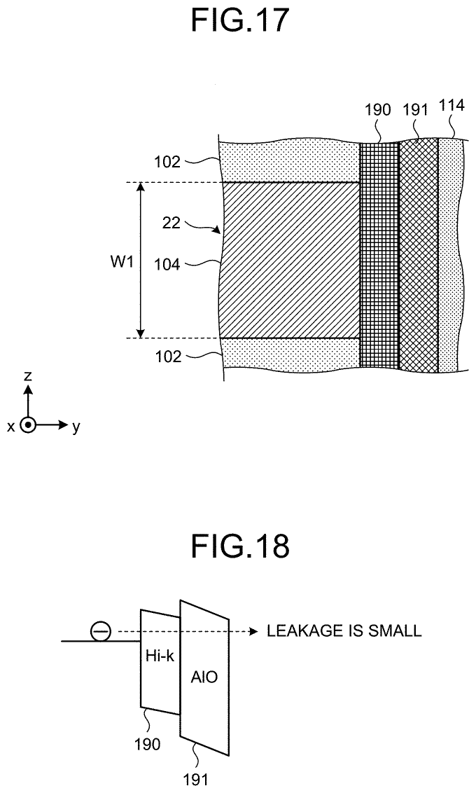

In the above-mentioned first embodiment, the Hi-k film 110 that is an oxide film containing tantalum and silicon, the block film 1120 made of aluminum oxide, and the block film 1121 made of silicon oxide are arranged between the electrode 104 and the electric-charge storing film 114. On the other hand, in the present embodiment, for example, as illustrated in FIG. 17, an Hi-k film 190 that is an oxide film containing tantalum and silicon, and a block film 191 made of aluminum oxide may be arranged between the electrode 104 and the electric-charge storing film 114.

FIG. 17 is a partial exploded view illustrating one example of a structure of a part in the region A according to a third embodiment. In the present embodiment, a film thickness of the Hi-k film 190 is 0.5 [nm] to 1 [nm], for example, a film thickness of the block film 191 is 2 [nm] to 4 [nm], for example, and a film thickness of the electric-charge storing film 114 is 3 [nm] to 5 [nm], for example. The Hi-k film 190 is one example of the first block film, and the block film 191 is one example of the second block film.

In the present embodiment, the block film 191 is made of aluminum oxide, and a content of silicon in the Hi-k film 190 is less than eight times as large as a content of tantalum. Therefore, an electric permittivity of the Hi-k film 190 is larger than an electric permittivity of the block film 191. Thus, in the semiconductor device 10 according to the present embodiment, the Hi-k film 190 and the block film 191 are arranged in the order of reducing electric permittivity from the electrode 104 to the electric-charge storing film 114.

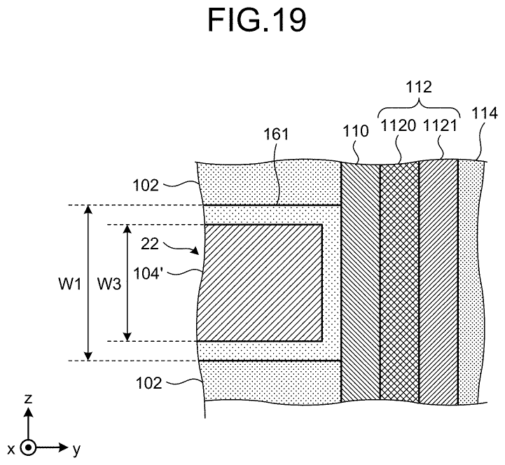

FIG. 18 is a diagram illustrating one example of relation between energy levels in the structure illustrated in FIG. 17. An electric permittivity of the Hi-k film 190 is larger than an electric permittivity of the block film 191 made of aluminum oxide, and thus reduction in a height of barrier of the Hi-k film 190 according to a distance from the electrode 104 is looser than that of the block film 191. Thus, in the present embodiment, it is also possible to prevent leakage of an electron between the electrode 104 and the electric-charge storing film 114.

[Others]

The disclosed technology is not limited to the above-mentioned embodiments, and various changes may be made without departing from the spirit of the embodiments.

For example, in the above-mentioned embodiments, the electrode 104 made of a metal other than tungsten is formed in the hole 22 between the interlayer insulating films 102 that are adjacent to each other in the z-direction; however, the disclosed technology is not limited thereto. For example, as illustrated in FIG. 19, the electrodes 104′ made of tungsten may be embedded in the hole 22 in which the barrier film 161 made of titanium nitride is laminated. FIG. 19 is a partial exploded view illustrating another example of a structure of a part in the region A according to the first embodiment.

In the example illustrated in FIG. 19, W3 that is CD of the electrodes 104′ is smaller than W1 that is CD of the hole 22 by a film thickness of the barrier film 161 that is laminated in the hole 22; on the other hand, is larger than W2 that is CD of the electrodes 104′ illustrated in FIG. 11. Thus, even in a case where tungsten is employed for a material of the electrode, it is possible to more reduce power consumption and heat generation of the semiconductor device 10 than those of the comparison example 1.

It should be considered that embodiments as disclosed herein are not limitative but are illustrative in any aspect. Indeed, the embodiments as described above can be implemented in various forms thereof. Furthermore, the embodiments as described above may be omitted, substituted, or modified in various forms thereof, without departing from the appended claims and the spirit thereof.

The present disclosure provides a semiconductor device that is capable of preventing leakage of an electron between an electrode and an electric-charge storing film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
an electric-charge storing film;
an electrode;
a first block film that is arranged between the electric-charge storing film and the electrode; and
a second block film that is arranged between the first block film and the electric-charge storing film, wherein
the first block film is an oxide film containing tantalum, and
an electric permittivity of the first block film is larger than an electric permittivity of the second block film.

2. The semiconductor device according to claim 1, wherein
the second block film includes:
a third block film made of aluminum oxide; and
a fourth block film made of silicon oxide, and
the third block film is arranged between the first block film and the fourth block film.

3. The semiconductor device according to claim 1, wherein
the second block film is made of aluminum oxide.

4. The semiconductor device according to claim 2, wherein
the first block film contains silicon, and
in the first block film, a content of silicon is less than eight times as large as a content of tantalum.

5. The semiconductor device according to claim 3, wherein
the first block film contains silicon, and
in the first block film, a content of silicon is less than eight times as large as a content of tantalum.

6. The semiconductor device according to claim 1, wherein
the second block film is made of silicon oxide.

7. The semiconductor device according to claim 6, wherein
the first block film contains silicon.
